(19) United States
(12) Patent Application Publication
(10) Pub. No.: US 2020/0144788 A1
(43) Pub. Date: May 7, 2020

(54) OPTICAL MODULATION DEVICE

(71) Applicant: Mitsubishi Electric Corporation, Tokyo (JP)

(72) Inventors: Kazuhisa TAKAGI, Tokyo (JP); Kyosuke KURAMOTO, Tokyo (JP)

(73) Assignee: Mitsubishi Electric Corporation, Tokyo (JP)

(21) Appl. No.: 16/473,347

(22) PCT Filed: Apr. 25, 2017
(86) PCT No.: PCT/JP2017/016381

§ 371 Date: Jun. 25, 2019

(51) Int. Cl. H01S 5/042; H01S 5/022; H01S 5/026

(52) U.S. Cl. CPC H01S 5/0427; H01S 5/4087; H01S 5/026; H01S 5/02236

(57) ABSTRACT

An optical modulation device includes a first optical modulator having a first capacitance, a second optical modulator having a second capacitance larger than the first capacitance, a first feed path having a first inductance and having one end connected to the first optical modulator, and a second feed path having a second inductance larger than the first inductance and having one end connected to the second optical modulator. In a graph having an abscissa axis of inductances and an ordinate axis of capacitance values, a predetermined range between a predetermined lower limit line and a predetermined upper limit line is set. The first capacitance, the first inductance, the second capacitance, and the second inductance are determined so that a first coordinate determined by the first capacitance and the first inductance and a second coordinate determined by the second capacitance and the second inductance are contained within the predetermined range.

### FIELD

The present invention relates to an optical modulation device.

### BACKGROUND

Conventionally, an optical modulation device in which plural optical modulators are integrated has been known as disclosed in JP 2015-138111 A, for example. This type of optical modulation device is used as a wavelength multiplexing transmitter. The wavelength multiplexing transmitter outputs an optical signal by multiplexing plural output lights emitted from plural electro-absorption modulator integrated semiconductor lasers which are different in wavelength. The optical modulation device according to this publication makes the element lengths of the plural optical modulators different from one another. More specifically, the element length of a specific optical modulator having an oscillation wavelength shorter than that of other optical modulators is set to be shorter than the element length of the other optical modulators. As a result, it is disclosed that an optical loss by an electro-absorption modulator on a lane in a short wave can be compensated without increasing the amount of current per unit length of the semiconductor laser.

### CITATION LIST

### Patent Literature

[PTL 1] JP 2015-138111 A

### SUMMARY

### Technical Problem

Each of the plural optical modulators is connected to a feed substrate via a feed path. The feed substrate provides an electrical signal to the optical modulator via the feed path. When a voltage is applied to the optical modulator by the electrical signal, an optical absorption end of the optical modulator is shifted according to the applied voltage. As a result, optical modulation is realized. The optical modulator has a parasitic capacitance, and the feed path has an inductance. Resonance caused by this capacitance and inductance appears in a frequency characteristic curve of the optical modulator. When the lengths of the plural feed paths are not equal to one another, the inductances of the plural feed paths are also not equal to one another. When the plural feed paths having varying inductances are connected to the plural optical modulators, the frequency characteristic greatly varies among the plural optical modulators. As a result, extinction ratio varies among the plural optical modulators, so that there is a problem that transmission quality is degraded.

As described in paragraph 0002 of JP 2015-138111 A, development of 100 Gigabit Ethernet (registered trademark) has been in progress as one of the standards constituting a next-generation ultra-high speed network. In LAN-WDM used in this standard, data of 25 Gb/s or 28 Gb/s is carried on each of four lights having different wavelengths. The four lights having the data carried thereon are multiplexed with one another to generate a signal of 100 Gb/s. In order to perform such data transmission with high quality, variation in frequency characteristic among plural optical modulators must be suppressed in a frequency region of 28 GHz or less.

The present invention has been made to solve the problem as described above, and has an object to provide an optical modulation device in which variation in frequency characteristic among plural optical modulators is suppressed in a frequency region of 28 GHz or less.

### Solution to Problem

To solve the above described problem, an optical modulation device includes: a first optical modulator having a first capacitance; a second optical modulator having a second capacitance larger than the first capacitance; a first feed path that has a first inductance and has one end connected to the first optical modulator; and a second feed path that has a second inductance larger than the first inductance and has one end connected to the second optical modulator. A gap between a predetermined lower limit straight line and a predetermined upper limit straight line is set as a predetermined range in a graph in which an abscissa axis is set for inductances and an ordinate axis is set for capacitance values. An inductance=670 nH and a capacitance value=0.05 pF in the graph define a first point, an inductance=1340 nH and a capacitance=0.11 pF in the graph define a second point, an inductance=2010 nH and a capacitance value=0.155 pF in the graph define a third point, the lower limit straight line is a straight line passing through the first point and the third point in the graph, the upper limit straight line is a straight line having a gradient equal to a gradient of the lower limit straight line and passing through the second point in the graph. The first inductance and the second inductance range from 670 nH to 2010 nH, and the first capacitance, the first inductance, the second capacitance and the second inductance are determined so that a first coordinate determined by the first capacitance and the first inductance and a second coordinate determined by the second capacitance and the second inductance are contained within the predetermined range.

### Advantageous Effect of Invention

According to the optical modulation device, the optical modulator and the feed path are designed so as to satisfy the correlation condition between the capacitance of the optical modulator and the inductance of the feed path disclosed in the present application. As a result, there is provided an optical modulation device in which variation in frequency characteristic among the plural optical modulators is suppressed in the frequency region of 28 GHz or less.

### BRIEF DESCRIPTION OF DRAWINGS

FIG. 1 is a plan view showing an optical modulation device according to a first embodiment.

FIG. 2 is a partially enlarged view of the optical modulation device according to the first embodiment.

FIG. 3 is a plan view showing an optical modulation device according to a modification of the first embodiment.

FIG. 4 is a graph showing an experimental result on the relationship between the lengths and capacitances of the optical modulators and the wire lengths of the feed paths.

FIG. 5 is a diagram showing an experimental result on the relationship between the capacitances of the optical modulators and the inductances of the feed paths.

FIG. 6 is a diagram showing an experimental result on the relationship between the capacitances of the optical modulators and the inductances of the feed paths.

FIG. 7 is a diagram showing an experimental result on the relationship between the capacitances of the optical modulators and the inductances of the feed paths.

FIG. 8 is a diagram showing an experimental result on the relationship between the capacitances of the optical modulators and the inductances of the feed paths.

FIG. 9 is a diagram showing an experimental result on the relationship between the capacitances of the optical modulators and the inductances of the feed paths.

FIG. 10 is a diagram showing an experimental result on the relationship between the capacitances of the optical modulators and the inductances of the feed paths.

FIG. 11 is a diagram showing an experimental result on the relationship between the capacitances of the optical modulators and the inductances of the feed paths.

FIG. 12 is a diagram showing an experimental result on the relationship between the capacitances of the optical modulators and the inductances of the feed paths.

FIG. 13 is a diagram showing an experimental result on the relationship between the capacitances of the optical modulators and the inductances of the feed paths.

FIG. 14 is a graph showing an experimental result and a review result on the relationship between the capacitances of the optical modulators and the inductances of the feed paths.

FIG. 15 shows experimental result on the terminating resistor.

FIG. 16 shows experimental result on the terminating resistor.

FIG. 17 shows experimental result on the terminating resistor.

FIG. 18 shows experimental result on the terminating resistor.

FIG. 19 shows experimental result on the terminating resistor.

FIG. 20 shows experimental result on the terminating resistor.

FIG. 21 shows experimental result on the terminating resistor.

FIG. 22 shows experimental result on the terminating resistor.

FIG. 23 shows experimental result on the terminating resistor.

FIG. 24 is a diagram showing a configuration of an optical modulation device according to a second embodiment.

FIG. 25 is a diagram showing a configuration of the optical modulation device according to the second embodiment.

FIG. 26 is a plan view showing an optical modulation device according to a comparative example to the embodiment.

FIG. 27 is a diagram showing the frequency characteristic of the optical modulation device according to the comparative example to the embodiment.

FIG. 28 is a diagram showing an experimental result on the relationship between the capacitances of the optical modulators and the inductances of the feed paths.

FIG. 29 is a diagram showing an experimental result on the relationship between the capacitances of the optical modulators and the inductances of the feed paths.

FIG. 30 is a diagram showing an experimental result on the relationship between the capacitances of the optical modulators and the inductances of the feed paths.

### DESCRIPTION OF EMBODIMENTS

### First Embodiment

### [Configuration of Device According to Embodiment]

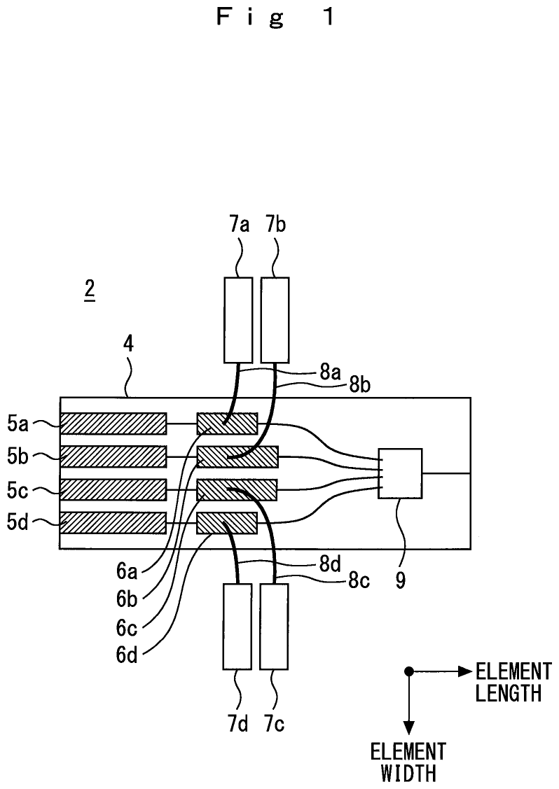

FIG. 1 is a plan view showing an optical modulation device 2 according to a first embodiment. The optical modulation device 2 according to the first embodiment includes a substrate 4, semiconductor laser elements 5a to 5d formed on the substrate 4, optical modulators 6a to 6d to which laser beams of the semiconductor laser elements 5a to 5d formed on the substrate 4 are input, an optical multiplexer 9 for multiplexing optical signals output from the optical modulators 6a to 6d, and feed substrates 7a to 7d connected to the optical modulators 6a to 6d through feed paths 8a to 8d. The semiconductor laser elements 5a to 5d are laser elements that oscillate in a single mode and emit laser beams having different wavelengths. Each of the optical modulators 6a to 6d is an electro-absorption optical modulator. The optical modulators 6a to 6d can generate an optical signal from the laser beam of each of the semiconductor laser elements 5a to 5d according to an input electric signal.

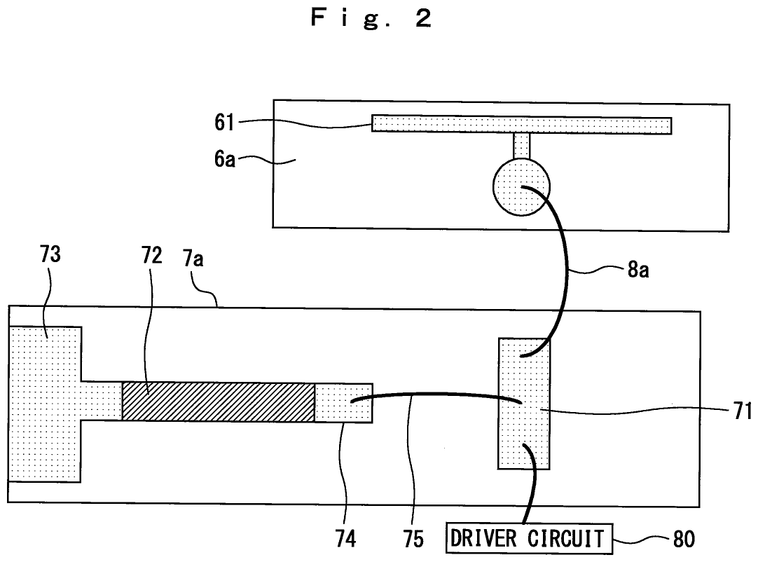

The optical modulators 6a to 6d are formed by laminating plural semiconductor layers and the like on a common substrate 4. The optical modulators 6a to 6d are configured by sequentially laminating an n-type cladding layer, a multiple quantum well core layer, a p-type cladding layer, a p-type contact layer, and the like on the substrate 4. As described later with reference to FIG. 2, the optical modulators 6a to 6d are provided with anode electrodes 61. The multiple quantum well core layers of the optical modulators 6a to 6d receive laser beams from the semiconductor laser elements 5a to 5d. Electric signals from the feed substrates 7a to 7d are input to the anode electrodes 61 of the optical modulators 6a to 6d. The optical absorption coefficients of the multiple quantum well core layers are controlled in accordance with the electrical signals. As a result, optical modulation can be performed in the optical modulators 6a to 6d. A monolithic optical modulation laser in which semiconductor laser elements and optical modulators are integrated on the same semiconductor substrate has already been known concerning the specific structure thereof, and thus further detailed description will be omitted. As coordinate axes are described in FIG. 1, an “element length” is a dimension as viewed in a direction parallel to optical axes of the laser beams of the semiconductor laser elements 5a to 5d passing through the optical modulators 6a to 6d. An “element width” is a dimension in a direction perpendicular to the “element length”. The element widths of the optical modulators 6a to 6d are equal to one another, but the element lengths are different from one another. As shown in FIG. 1, the optical modulators 6b and 6c are longer than the optical modulators 6a and 6d.

The optical modulators 6a to 6d are connected to the feed substrates 7a to 7d via the feed paths 8a to 8d. In the first embodiment, the feed paths 8a to 8d are wires which are made of the same material and have the same thickness. The feed paths 8a to 8d are different in wire length from one another, and the feed paths 8b and 8c are longer than the feed paths 8a and 8d.

In the optical modulation device 2, the optical modulators 6b and 6c having long element lengths are connected to the feed substrates 7b and 7c via the feed paths 8b and 8c having long wire lengths. Furthermore, in the optical modulation device 2, the optical modulators 6a and 6c having short element lengths are connected to the feed substrates 7a and 7c via the feed paths 8a and 8c having short wire lengths.

In the first embodiment, the capacitances of the optical modulators 6a to 6d and the inductances of the feed paths 8a to 8d are determined as follows. The composition of each layer of the optical modulators 6a to 6d and the thickness of each layer of the optical modulators 6a to 6d are equal among the optical modulators 6a to 6d. Accordingly, “unit element length capacitance” which is the capacitance per unit element length of the optical modulators 6a to 6d is equal among the optical modulators 6a to 6d. The capacitance of each of the optical modulators 6a to 6d is determined by the product of the “unit element length capacitance” and the element length of each of the optical modulators 6a to 6d. Therefore, the capacitances of the optical modulators 6b and 6c having relatively long element lengths are larger than the capacitances of the optical modulators 6a and 6d. Furthermore, the inductance of each of the feed paths 8a to 8d is determined by the product of the “feed path length” and the “unit length inductance”. Accordingly, among the feed paths 8a to 8d, the relatively long feed paths 8b and 8c have larger inductances than the relatively short feed paths 8a and 8d. In the relationship between the capacitance and the inductance, the optical modulators having the large capacitances among the optical modulators 6a to 6d are connected to the feed substrates 7a to 7d through the feed paths having the large inductances among the feed paths 8a to 8d. In the first embodiment, the capacitances of the optical modulators 6a to 6d and the inductances of the feed paths 8a to 8d are set so as to satisfy a design condition defined in a predetermined range Q which is predetermined in a graph of FIG. 14. As a result, the optical modulation device 2 in which variation of extinction ratio among the plural optical modulators 6a to 6d is suppressed is provided.

FIG. 2 is a partially enlarged view of the optical modulation device 2 according to the first embodiment. The vicinity of the anode electrode 61 of the optical modulator 6a and the feed substrate 7a in the optical modulation device 2 are representatively shown. Although illustration is omitted, the feed substrates 7b to 7d have the same structure as the feed substrate 7a. It is assumed that the optical modulators 6b to 6c are also connected to the feed substrates 7b to 7d as in the case of FIG. 2. The feed substrate 7a includes a terminating resistor 72 and a ground electrode 73. One end of the terminating resistor 72 is connected to the anode electrode 61 of the optical modulator 6a via a line 74, a wire 75, an electrode pad 71, and the feed path 8a. The other end of the terminating resistor 72 is connected to the ground electrode 73. The electrode pad 71 is connected to a driver circuit 80 via a wire. An electrical signal is input from the driver circuit 80 to the anode electrode 61.

In the first embodiment, a bit rate of signals for driving the optical modulators 6a to 6d is set to 30 Gb/s or less. The reason is as follows: in recent years, ultra-high-speed optical communication of 100 Gb/s has been increasingly demanded. At present, it is difficult to realize long-distance transmission of 25 km to 40 km at a bit rate of 40 Gb/s or more in high speed optical communication using an electro-absorption modulator integrated semiconductor laser. A solution for the difficulty is a wavelength multiplexing transmission technique that achieves 100 Gb/s by multiplexing four 28 Gb/s optical signals having different wavelengths. This wavelength multiplexing transmission technique is also used in the first embodiment. In the first embodiment, the bit rate is set to 30 Gb/s or less as a value in which a margin is expected for 28 Gb/s.

Describing this point in detail, as described in paragraph 0002 of JP 2015-138111 A, development of 100 Gigabit Ethernet (registered trademark) as one of the standards constituting the next generation ultra-high-speed network is advancing. Particularly, 100GBASE-LR4 and 100GBASE-ER4 that exchange data between buildings at a middle or long distance of 10 km or less or exchange data between remote buildings at a distance of 40 km or less are considered to be promising. LAN-WDM is used in the above standard. In LAN-WDM, data of 25 Gb/s or 28 Gb/s is carried on each of four lights having different wavelengths. The four lights carrying data thereon are multiplexed to generate a signal of 100 Gb/s. As an example of each wavelength of the four lights, a first wavelength is set to 1294.53 to 1296.59 nm, a second wavelength is set to 1299.02 to 1301.09 nm, a third wavelength is set to 1303.54 to 1305.63 nm, and a fourth wavelength is set to 1308.09 to 1310.19 nm. In the first embodiment, it is preferable that the optical modulation device 2 is designed so that the respective wavelengths of the semiconductor laser elements 5a to 5d are equal to the first to fourth wavelengths, respectively.

(Another Example of Device Configuration)

FIG. 3 is a plan view showing an optical modulation device 12 according to a modification of the first embodiment. In the optical modulation device 12 of FIG. 3, the element lengths of the optical modulators 16a to 16d and the lengths of the feed paths 18a to 18d are different from those of the configuration of FIG. 1. With respect to the element lengths of the optical modulators 16a to 16d, the element length is gradually shortened in the order of the optical modulators 16a, 16b, 16c, and 16d. With respect to the lengths of the feed paths 18a to 18d, the length is gradually shortened in the order of the feed paths 18a, 18b, 18c, and 18d.

Regarding the relationship between the capacitance and the inductance, the same relationship as the optical modulation device 2 is also established in the optical modulation device 12. That is, an optical modulator having a larger capacitance out of the optical modulators 16a to 16d is connected to the feed substrate 7a to 7d via a feed path having a larger inductance out of the feed paths 18a to 18d. In the modification of FIG. 3, in a graph of FIG. 14 described later, each of coordinates determined by the capacitances of the optical modulators 16a to 16d and the inductances of the feed paths 18a to 18d is contained within a predetermined range Q.

There is a difference in wire bond structure between FIG. 1 and FIG. 3. When the feed paths 8a to 8d are connected to the optical modulators 16a to 16d from both sides of the substrate 4 as shown in FIG. 1, the variation in the wire length among the feed paths 8a to 8d can be reduced. On the other hand, when the feed paths 18a to 18d are connected from one side of the substrate 4 as shown in FIG. 3, the wire lengths of the feed paths 18a to 18d can be easily made different from one another, and the feed substrates 7a to 7d can be arranged in alignment with one another on one side of the substrate 4.

### [Design Technique According to Embodiment]

### (Design Conditions of Optical Modulator and Feed Path)

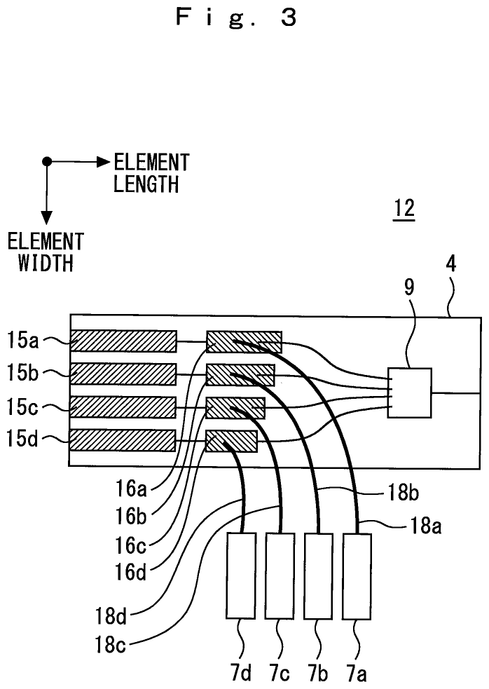

FIG. 4 is a graph showing an experimental result on the relationship between the lengths and capacitances of the optical modulators 6a to 6d and the wire lengths of the feed paths 8a to 8d. Since the optical modulators 6a to 6d have the same capacitance per unit element length, the scale of the capacitance value in FIG. 4 can be obtained by multiplying the element length of each of the optical modulators 6a to 6d by the capacitance per unit element length. A point PE1 is a value when the wire length of the feed paths 8a to 8d is equal to 100 μm and the element length of the optical modulators 6a to 6d is equal to 100 μm, that is, the capacitance is equal to 0.05 pF. A point PE2 is a value when the wire length of the feed paths 8a to 8d is equal to 200 μm and the element length of the optical modulators 6a to 6d is equal to 220 μm, that is, the capacitance is equal to 0.11 pF. A point PE3 is a value when the wire length of the feed paths 8a to 8d is equal to 300 μm and the element length of the optical modulators 6a to 6d is equal to 280 μm, that is, the capacitance is equal to 0.14 pF. A characteristic curve determining the relation between the optimum length dimension of the optical modulator and the wire length as an approximate curve is obtained based on the points PE1 to PE3. According to an experiment of the inventor of the present application, it has been confirmed that flat preferable frequency characteristics are exhibited at 28 GHz or less at points PE1 to PE3.

By performing regression analysis using the points PE1 to PE3, a regression line R shown in FIG. 4 can be obtained. The regression line R can be expressed by the following regression equation (1).

y=0.0004x+0.01 (1)

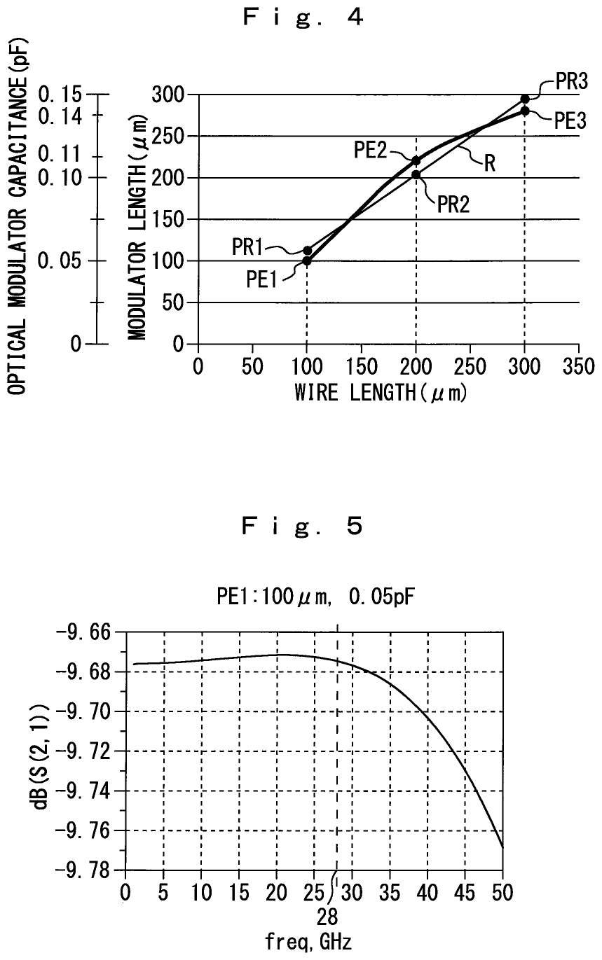

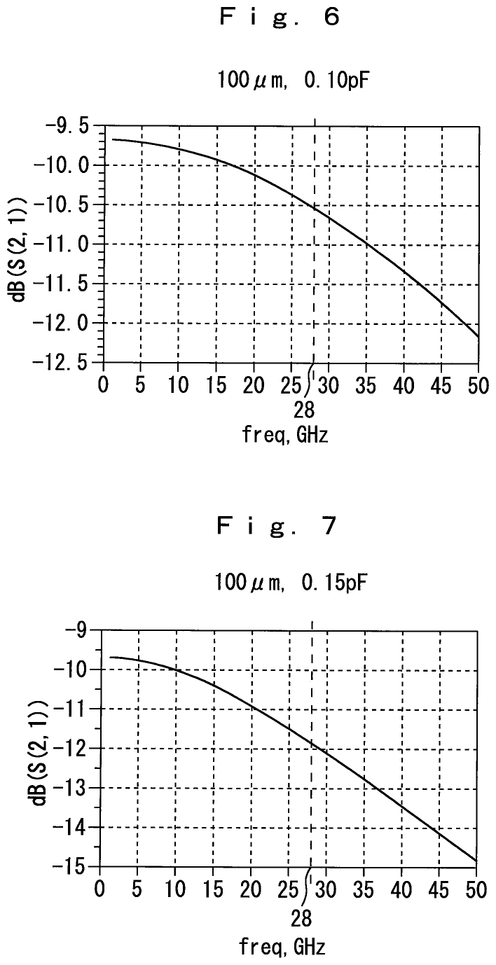

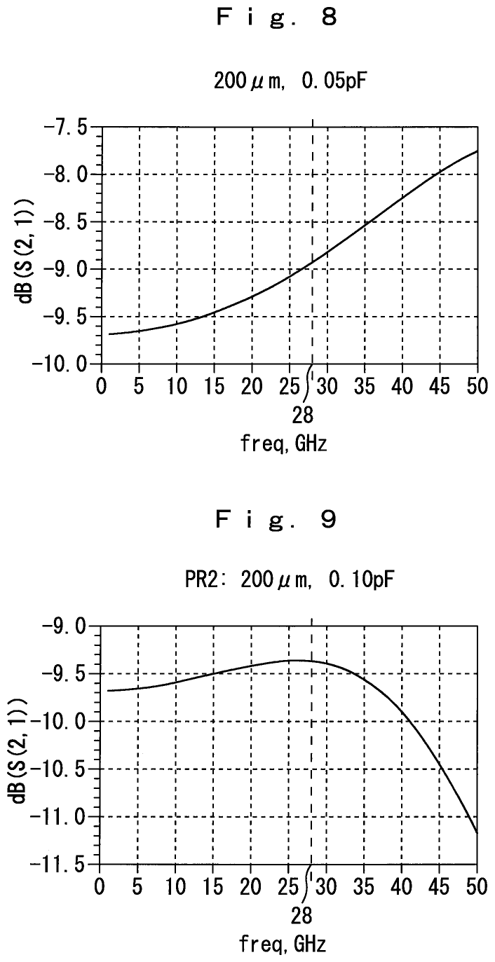

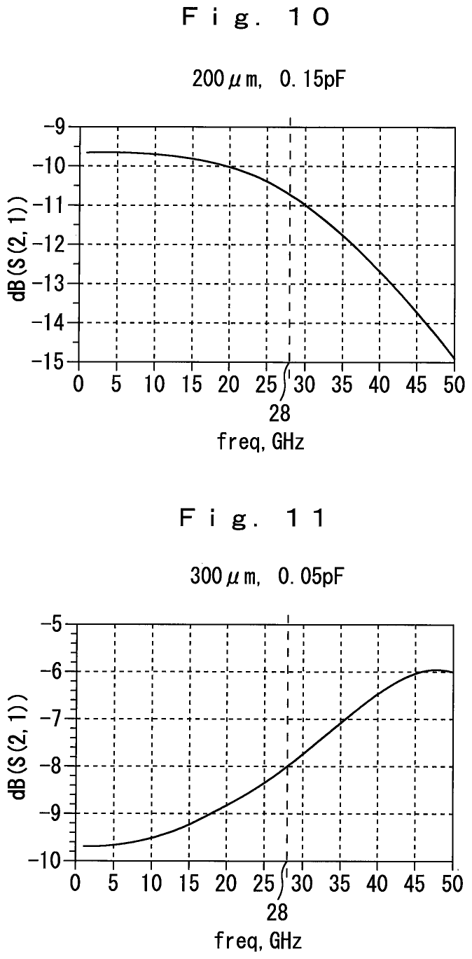

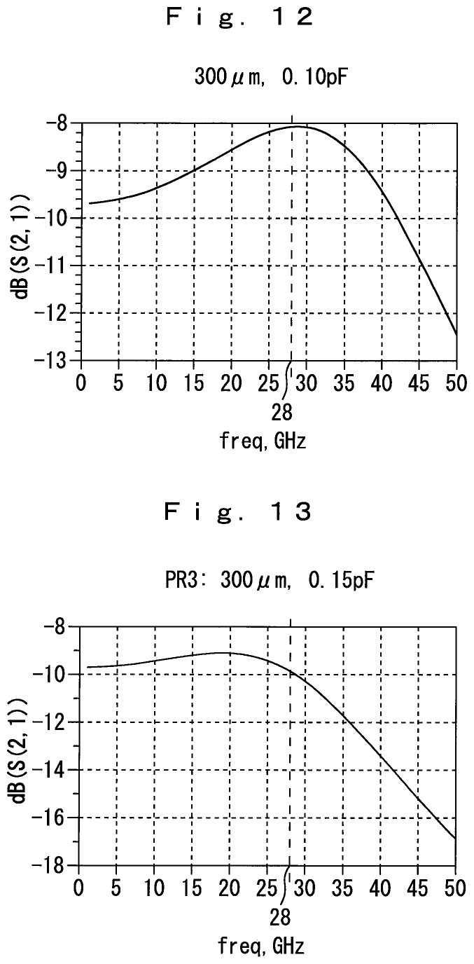

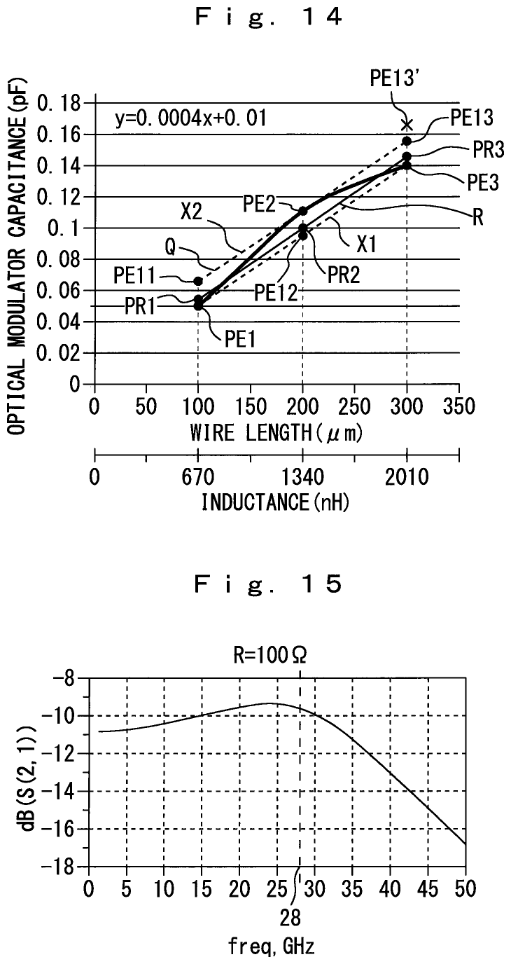

FIGS. 5 to 13 and FIGS. 28 to 30 are diagrams showing experimental results on the relationship between the capacitances of the optical modulators 6a to 6d and the inductances of the feed paths 8a to 8d. FIGS. 4 to 12 show the relationship among the frequency characteristic of power applied to the optical modulators 6a to 6d, the wire lengths of the feed paths 8a to 8d, and the capacitances of the optical modulators 6a to 6d. The point PE1 in FIG. 4 corresponds to the characteristic at the wire length of 100 μm and the capacitance of 0.05 pF shown in FIG. 5. Although the value of 100 μm of the regression line R is strictly slightly above 0.05 pF, the regression equation (1) in the first embodiment is set such that the approximate value of the capacitance at 100 μm is calculated as 0.05 pF. The point PR2 in FIG. 4 corresponds to the characteristic at the wire length of 200 μm and the capacitance of 0.10 pF shown in FIG. 9. The point PR3 in FIG. 4 corresponds to the characteristic at the wire length of 300 μm and the capacitance of 0.15 pF shown in FIG. 13. The frequency characteristics shown in FIG. 5, FIG. 9 and FIG. 13 respectively show flat preferable characteristics at 28 GHz or less. Accordingly, the regression equation (1) represents the correlation between the capacitance and the wire length for obtaining preferable frequency characteristics.

FIG. 14 is a graph showing an experimental result and a review result on the relationship between the capacitances of the optical modulators 6a to 6d and the inductances of the feed paths 8a to 8d. A lower limit straight line X1 and an upper limit straight line X2 in FIG. 14 are set as follows by using the experimental result shown in FIG. 4. The lower limit straight line X1 is a straight line passing through the point PE1 and the point PE3. The upper limit straight line X2 is a straight line having the same inclination as the lower limit straight line and passing through the point PE2. A predetermined range Q is set in the graph of FIG. 14. The predetermined range Q is a range which is preset so as to be not less than the lower limit straight line X1 and not more than the upper limit straight line X2 in the graph of FIG. 14.

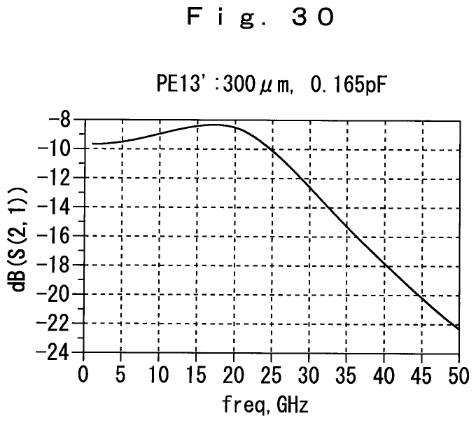

The point PE12 in FIG. 14 indicates a capacitance value at the wire length of 200 μm of the lower limit straight line X1. The capacitance value of the point PE12 is equal to about 0.095 pF. Points PE11 and PE13 in FIG. 14 indicate capacitance values at the wire lengths of 100 μM and 300 μm of the upper limit straight line X2. The capacitance values at the points PE11 and the point PE13 are equal to about 0.065 pF and about 0.155 pF, respectively. FIGS. 28 to 29 show frequency characteristics for the points PE11 and PE12. The characteristic at the wire length of 100 μm and the capacitance of 0.065 pF shown in FIG. 28 and the characteristic at the wire length of 200 μm and the capacitance of 0.095 pF shown in FIG. 29 respectively show flat preferable frequency characteristics at 28 GHz or less. FIG. 30 shows the characteristic at the wire length of 300 μm and the capacitance of 0.165 pF, and corresponds to a point PE13′ in FIG. 14. The characteristic at the wire length of 300 μm and the capacitance of 0.165 pF shown in FIG. 30 likewise shows flat preferable frequency characteristic. The point PE13 corresponding to 0.155 pF and 300 μm exists between the point PE13′ and the point PE3. Therefore, a good frequency characteristic can also be obtained at the point PE13 as well as in the case of the points PE13′ and the point PE3.

From the experimental results of FIGS. 5, 9, 13 and 28 to 30, it is found that the bulge of the frequency characteristic curve is sufficiently small at 28 GHz or less in the frequency characteristic of each of the points PE1 to PE13. Therefore, in the first embodiment, the predetermined range Q is set by the points PE1 to PE13. The wire lengths of the feed paths 8a to 8d are from 100 μm to 300 μm in the predetermined range Q, and the predetermined range Q is surrounded by the upper limit straight line X2 and the lower limit straight line X1. In the first embodiment, a design of combining the capacitances of the optical modulators 6a to 6d and the wire lengths of the feed paths 8a to 8d is performed so that the capacitances of the optical modulators 6a to 6d and the wire lengths of the feed paths 8a to 8d are contained within the predetermined range Q. In other words, in a design stage, a first coordinate determined by the capacitance of the optical modulator 6a and the wire length of the feed path 8a, a second coordinate determined by the capacitance of the optical modulator 6b and the wire length of the feed path 8b, a third coordinate determined by the capacitance of the optical modulator 6c and the wire length of the feed path 8c, and a fourth coordinate determined by the capacitance of the optical modulator 6d and the wire length of the feed path 8d can be plotted in the graph of FIG. 14 in which the abscissa axis is set for the wire length and the ordinate axis is set for the capacitance value. The capacitance of each of the optical modulators 6a to 6d and the wire length of each of the feed paths 8a to 8d are set so that all the first to fourth coordinates are contained within the predetermined range Q. As a result, the variation of the frequency characteristic among the plural optical modulators 6a to 6d is suppressed in the frequency region of 28 GHz or less. This provides the optical modulation device 2 in which the variation of the extinction ratio among the plural optical modulators 6a to 6d is suppressed.

A review result on the capacitance and the wire length can be generalized as follows. As a result, the design technique according to the first embodiment can be applied to a case where feed members other than the wires are used as the feed paths 8a to 8d in the optical modulation device 2. The inductance per unit length of the wires used as the feed paths 8a to 8d is equal to 6.7 nH/μm. The scale of the wire length is multiplied by the inductance per unit length, whereby an inductance scale added on the abscissa axis of FIG. 14 is obtained. A wire length of 100 μm corresponds to an inductance of 670 nH, a wire length of 200 μm corresponds to an inductance of 1340 nH, and a wire length of 300 μm corresponds to an inductance of 2010 nH. In the graph of FIG. 14 in which the abscissa axis is set for the inductance and the ordinate axis is set for the capacitance, the capacitance of each of the optical modulators 6a to 6d and the inductance of each of the feed paths 8a to 8d may be set so that the coordinate determined by the capacitance and the inductance is contained within the predetermined range Q. This makes it possible to design the optical modulation device 2 so as to satisfy the correlation condition between the capacitances of the optical modulators 6a to 6d and the inductances of the feed paths 8a to 8d disclosed in the present application. As a result, the variation of the frequency characteristic among the plural optical modulators 6a to 6d is suppressed in the frequency region of 28 GHz or less. This provides the optical modulation device 2 in which the variation of the extinction ratio among the plural optical modulators 6a to 6d is suppressed.

### (Regression Analysis)

The above-described regression equation (1) may be applied to design the optical modulators 6a to 6d and the feed paths 8a to 8d according to a relationship as described below.

The capacitance per unit element length (pF/μm)×the element length of the optical modulator (μm)=0.0004×the wire length (μm) (2)

Based on the above equation (2), the optical modulators 6a to 6d and the feed paths 8a to 8d may be designed so as to satisfy the capacitance of the optical modulator 6a/the wire length of the feed path 8a=the capacitance of the optical modulator 6b/the wire length of the feed path 8b=the capacitance of the optical modulator 6c/the wire length of the feed path 8c=the capacitance of the optical modulator 6d/the wire length of the feed path 8d=0.0004.

The following relational expression (3) can be obtained by generalizing the above expression (2) using the inductance per unit length. The optical modulators 6a to 6d and the feed paths 8a to 8d may be designed using this equation (3).

{The capacitance per unit element length (pF/μm)×the element length of the optical modulator (μm)}/{the inductance of the feed path per unit length (nH/μm)×the feed path length (μm)}=6.0×10⁻⁵ (3)

Based on the above equation (3), the optical modulators 6a to 6d and the feed paths 8a to 8d may be designed so as to satisfy the following equation (4).

The capacitance of the optical modulator 6a/the inductance of the feed path 8a=the capacitance of the optical modulator 6b/the inductance of the feed path 8b=the capacitance of the optical modulator 6c/the inductance of the feed path 8c=the capacitance of the optical modulator 6d/the inductance of the feed path 8d=6.0×10⁻⁵ (4)

### Comparative Example

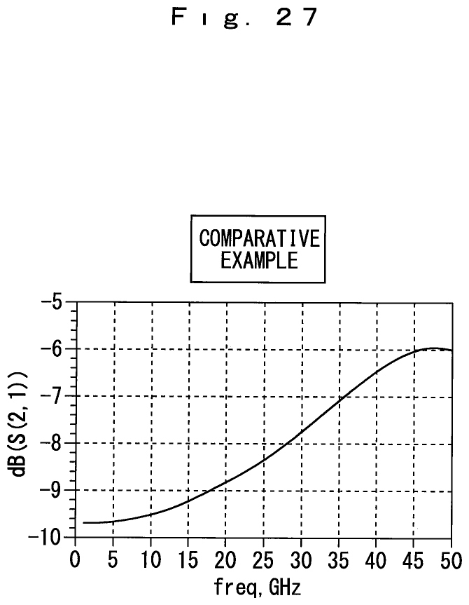

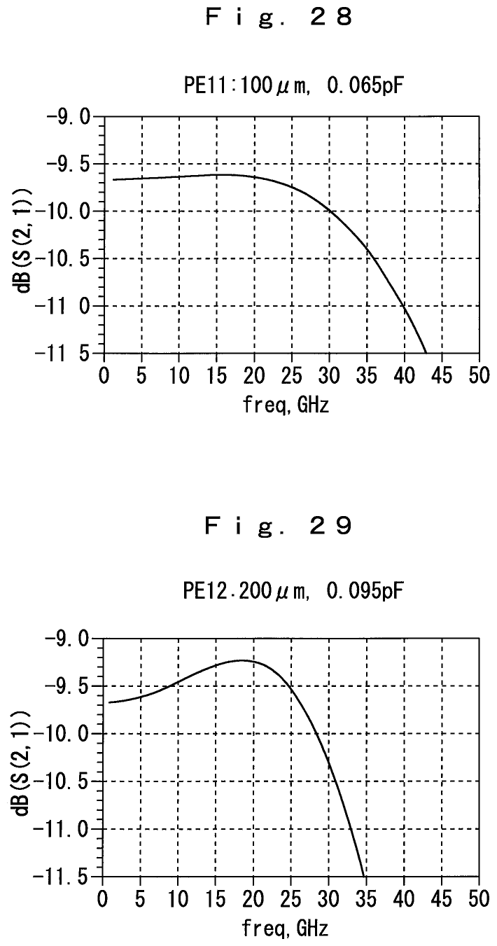

FIG. 26 is a plan view showing an optical modulation device 102 according to a comparative example to the embodiment. In the optical modulation device 102 according to the comparative example, all the optical modulators 106a to 106d have the same element length. FIG. 27 is a diagram showing the frequency characteristic of the optical modulation device 102 according to the comparative example to the embodiment. In the optical modulation device 102, variation occurs in the high-frequency characteristic among the plural optical modulators 106a to 106d due to the respective differences among the lengths of the feed paths of the plural optical modulators 106a to 106d. That is, as the feed paths 8a to 8d become longer, the rising of the frequency characteristic becomes larger. As a result, the optical modulation device 102 according to the comparative example has a problem that the extinction characteristic varies among the plural optical modulators 106a to 106d. The cause of this problem resides in that resonance occurs in the vicinity of 48 GHz due to the parasitic capacitances of the optical modulators 106a to 106d and the inductances of the feed paths 8a to 8d as shown in FIG. 27.

In this respect, in the first embodiment, the optical modulation device 2 is designed such that the capacitances of the optical modulators 6a to 6d and the inductances of the feed paths 8a to 8d have the predetermined condition described in the above design technique. Therefore, the optical modulation device 2 in which the variation in extinction ratio among the plural optical modulators 6a to 6d is suppressed is provided.

### (Design of Terminating Resistor)

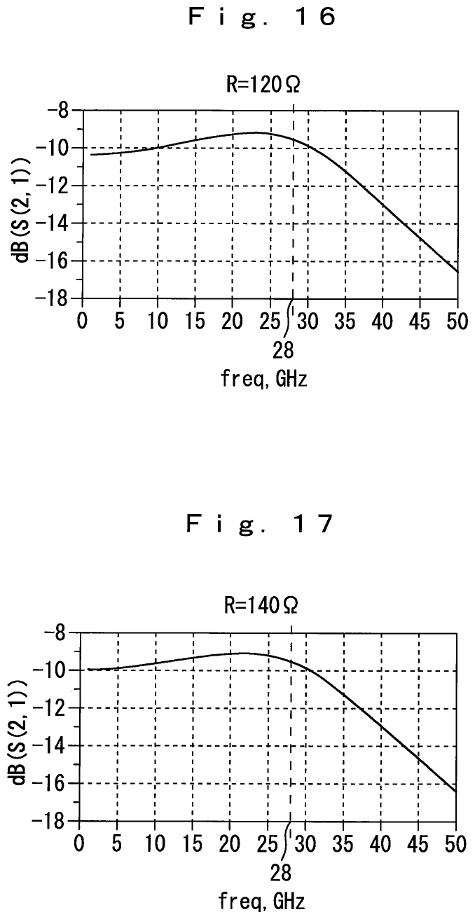

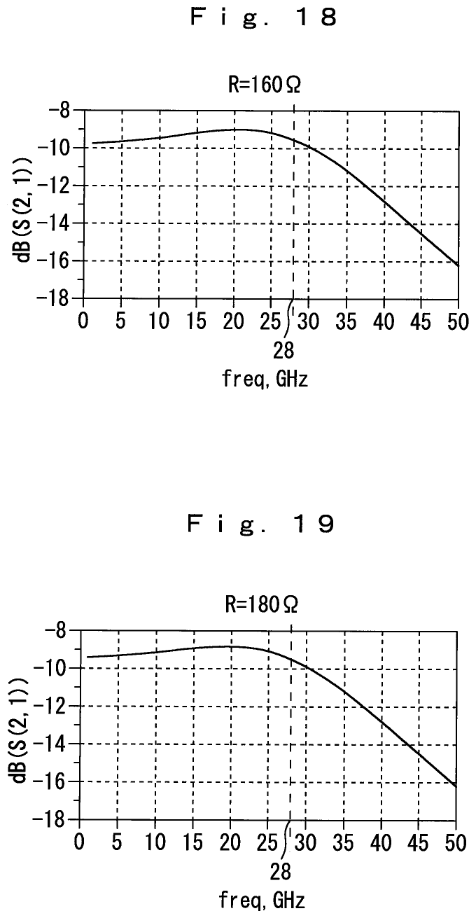

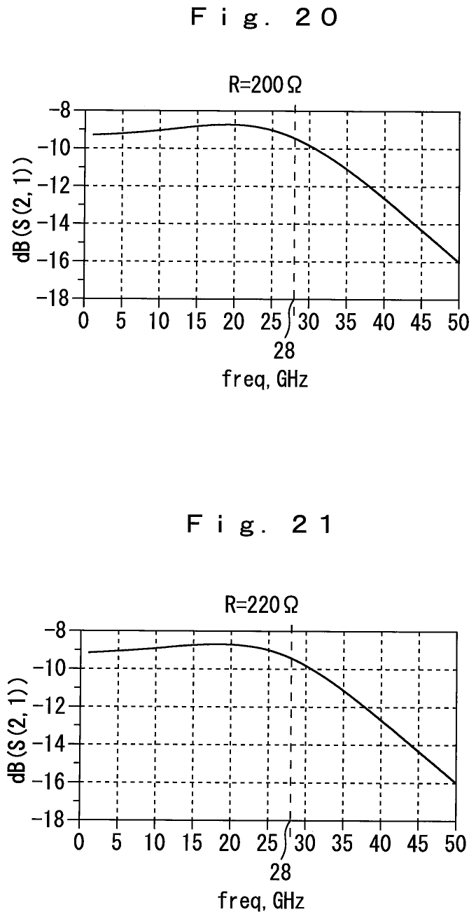

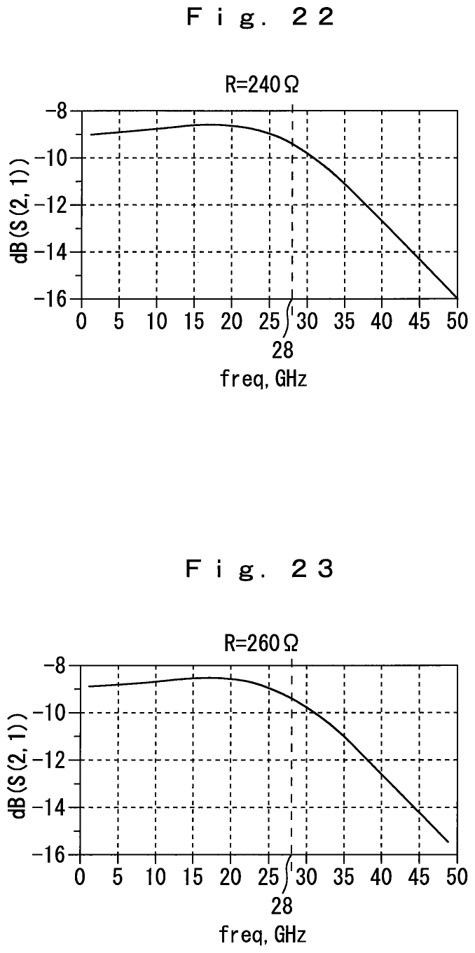

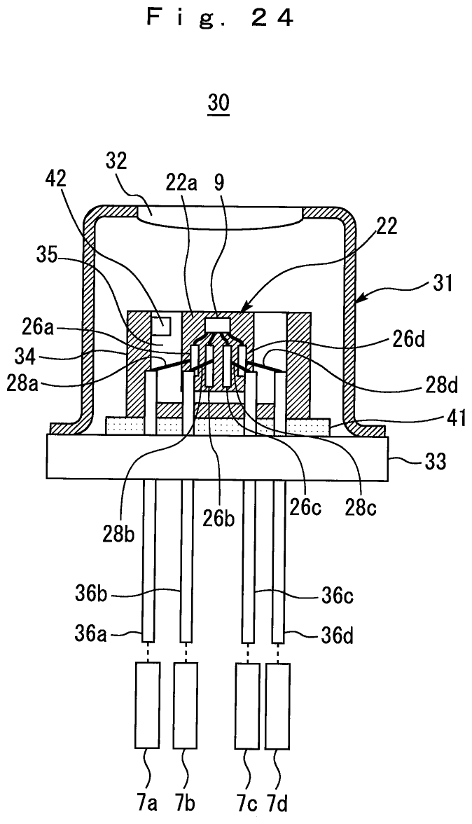

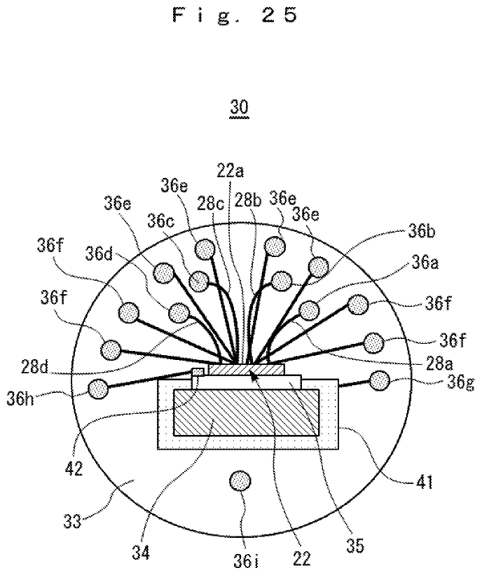

FIGS. 15 to 23 show experimental results on the terminating resistor 72. The results obtained by examining the frequency characteristic while changing the resistance value R of the terminating resistor 72 from 100 to 260 Q are shown. At R=100Ω, a frequency response greatly bulges in a range from 20 GHz to 25 GHz. When such bulge is too large, deterioration of a modulation waveform causes a problem. It is preferable that the bulge of the frequency response be suppressed to 1 dB or less. The inventor of the present invention has confirmed that when the resistance value of the terminating resistor 72 is equal to 120 Q or more, the bulge of the frequency response is within an allowable range. By setting the terminating resistor to 120Ω or more in the optical modulation device 2 according to the first embodiment, the bulge of the frequency characteristic curve in the frequency region of 28 GHz or less can be suppressed within the allowable range.

### Another Modification of Embodiment

Under the design condition based on the predetermined range Q and the regression line R in the graph of FIG. 14 described above, the magnitude of the capacitances of the optical modulators 6a to 6d are used as design parameters. The structures of the optical modulators 6a to 6d are not limited to the specific structure of the first embodiment described above, and no limitation is also imposed on the manufacturing method thereof. The structures of the optical modulators 6a to 6d may be any of vertical ridge type, buried type and high-mesa type. Even when deformation is performed so that the element widths of the optical modulators 6a to 6d are different from one another or deformation is performed so that the thicknesses and compositions of the semiconductor multilayer structures of the optical modulators 6a to 6d are different from one another, the design technique of the first embodiment can be applied by calculating or measuring the capacitance of each of the optical modulators 6a to 6d.

In the design condition based on the graph of FIG. 14 and the regression line R described above, the magnitude of the inductances of the feed paths 8a to 8d are used as design parameters. Feed members other than wires may be used for the feed paths 8a to 8d. For example, ribbon feeders can be used instead of wires as the feed paths 8a to 8d. The inductance of each of the feed paths 8a to 8d can be determined by multiplying the inductance per unit length of the feed member to be used by the length of the feed member to be used. For example, some of the feed paths 8a to 8d may be made of wires, and the other feed paths may be made of other feed members such as ribbon feeders. By making the thicknesses of the wires different from one another, the inductances can also be made different from one another.

The predetermined range Q in the graph of FIG. 14 can also be deformed by using the regression equation (1). In other words, another predetermined range having the upper limit straight line X2 as an upper limit and the regression line R as a lower limit may be set. Alternatively, another predetermined range having the regression line R as an upper limit and the lower limit straight line X1 as a lower limit may be set as another modification. In these two modifications, a range narrower than the predetermined range Q can be set as the design condition. The capacitance of each of the optical modulators 6a to 6d and the inductance of each of the feed paths 8a to 8d may be designed so that the coordinate determined by the capacitance and the inductance is contained in the predetermined ranges according to these modifications in the graph of FIG. 14 in which the abscissa axis represents the inductance and the ordinate axis represents the capacitance.

In the first embodiment, the four-wavelength integrated optical modulation device 2 in which four pairs of semiconductor laser elements and optical modulators are provided. However, the design technique of the first embodiment 1 can be applied to an optical modulation device in which two or more pairs of semiconductor laser elements and optical modulators are provided.

### Second Embodiment

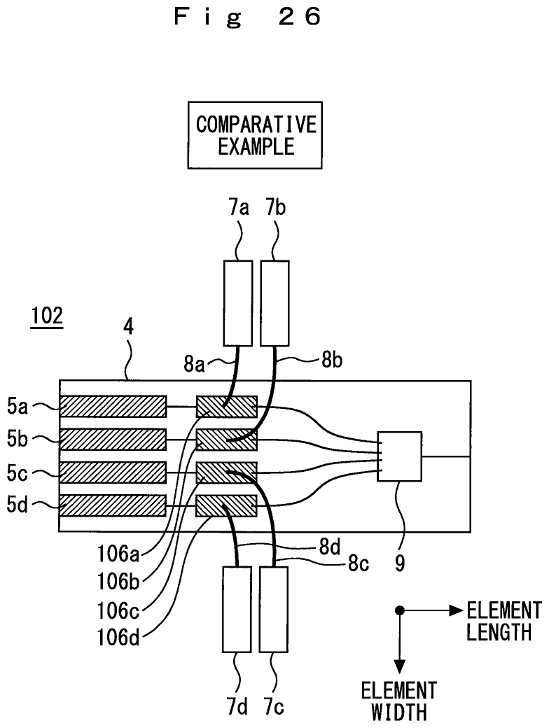

In the following description, the same or corresponding components as or to those of the first embodiment will be represented by the same reference numerals, differences from the first embodiment will be mainly described, and description on common matters will be simplified or omitted. FIG. 24 is a diagram showing a configuration of an optical modulation device 30 according to a second embodiment. As shown in FIG. 24, the optical modulation device 30 includes an optical modulator integrated laser chip 22, feed paths 28a to 28d, a cap 31, a stem 33, a block 34, a sub mount 35, plural lead pins 36a to 36d, a Peltier element 41, and a thermistor 42. In FIG. 24, the inside of the optical modulation device 30 is illustrated by cutting the cap 31. The Peltier element 41 is provided on the top surface of the stem 33. The block 34 is provided on the Peltier element 41. The block 34 has a top surface, a bottom surface and a side surface, and the bottom surface is mounted on the Peltier element 41. The sub mount 35 is provided on the side surface of the block 34.

The optical modulator integrated laser chip 22 is mounted on the surface of the sub mount 35. Plural semiconductor laser elements (not shown) are provided on the main surface 22a of the optical modulator integrated laser chip 22 as in the case of the first embodiment. Plurality of optical modulators 26a to 26d and an optical multiplexer 9 are formed on the main surface 22a of the optical modulator integrated laser chip 22. Although illustration is omitted, the plural optical modulators 26a to 26d are provided with the anode electrodes 61 shown in FIG. 2. Although illustration is omitted, plural monitor photodiodes for monitoring the operating states of the respective semiconductor laser elements are formed in the optical modulator integrated laser chip 22.

The thermistor 42 is provided to be adjacent to the optical modulator integrated laser chip 22 on the surface of the sub mount 35. The plural lead pins 36a to 36d are inserted in through-holes of the stem 33. An insulator such as glass is sandwiched between the through-holes of the stem 33 and the lead pins 36a to 36d, and the stem 33 is electrically insulated from the lead pins 36a to 36d. The cap 31 is placed on the top surface of the stem 33 and covers a structure provided on the top surface of the stem 33. The cap 31 has a window 32 for passing multiplexed light from the optical multiplexer 9.

The element lengths of the optical modulators 26b and 26c are longer than the element lengths of the optical modulators 26a and 26d. The feed paths 28a to 28d connect the lead pins 36a to 36d and the optical modulator integrated laser chip 22. In the second embodiment, as in the case of the first embodiment, the feed paths 28a to 28d are formed of wires which are formed of the same material and have the same thickness. The lead pins 36a to 36d are respectively connected to the feed substrates 7a to 7d which are similar to those of the first embodiment.

FIG. 25 is a diagram showing a configuration of the optical modulation device 30 according to the second embodiment. Although only the lead pins 36a to 36d connected to the optical modulators 26a to 26d via the feed paths 28a to 28d are shown in FIG. 24 for convenience's sake of description in FIG. 24, actually, a total of 15 lead pins are provided as shown in FIG. 25. FIG. 25 is a diagram when the top surface of the stem 33 is viewed from above.

As is apparent from FIG. 25, the feed paths 28b and 28c connected to the optical modulators 26b and 26c are longer than the feed paths 28a and 28d connected to the optical modulators 26a and 26d. In the second embodiment, the capacitances of the optical modulators 26a to 26d and the inductances of the feed paths 28a to 28d are set so as to satisfy the design condition defined by the predetermined range Q of the graph of FIG. 14 as in the case of the first embodiment. As a result, the optical modulation device 30 in which the variation in extinction ratio among the plural optical modulators 26a to 26d is suppressed is provided.

The optical modulation device 30 also includes lead pins 36e to 36i in addition to the lead pins 36a to 36d. As shown in FIG. 25, when the top surface of the stem 33 is viewed in plan, the lead pins 36a to 36d are arranged above the main surface 22a of the optical modulator integrated laser chip 22. In top view of the stem 33, the lead pins 36e to 36i are arranged outside the lead pins 36a to 36d so as to surround the block 34.

The lead pin 36i is a lead pin for common ground. The four lead pins 36e are connected to respective anodes of four semiconductor laser elements (not shown) formed in the optical modulator integrated laser chip 22 via wires. The four lead pins 36f are connected to respective anodes of four monitor photodiodes (not shown) formed in the optical modulator integrated laser chip 22 via wires. The lead pin 36g is connected to the Peltier element 41 via a wire. The lead pin 36h is connected to the thermistor 42 via a wire.

Electrical signals are supplied from the feed substrates 7a to 7d to the anode electrodes 61 of the optical modulators 26a to 26d via the feed paths 28a to 28d and the lead pins 36a to 36d. In the second embodiment, the lead pins 36a to 36d are formed of the same material and have the same thickness and length, so that there is not any structural difference causing a difference in inductance. Accordingly, as in the case of the optical modulation device 30 according to the first embodiment, the lengths of the feed paths 28a to 28d and the element lengths of the optical modulators 26a to 26d may be designed so that each coordinate determined from a combination of the inductance of each of the feed paths 28a to 28d and the capacitance of each of the optical modulators 26a to 26d is contained within the predetermined range Q in the graph of FIG. 14.

In the second embodiment, various modifications similar to those described in the first embodiment are possible. For example, as shown in FIG. 3, the element lengths of the optical modulators 26a, 26b, 26c, and 26d may be gradually increased or decreased in this order so that all the optical modulators 26a to 26d have different element lengths from one another. The arrangement of the lead pins 36a to 36d in the stem 33 may be modified. When the lead pins 36a to 36d are aligned above the main surface 22a of the optical modulator integrated laser chip 22 as shown in FIG. 25, there is an effect of reducing variation among the wire lengths of the feed paths 28a to 28d like the effect obtained by the structure of FIG. 1. However, the arrangement of the lead pins 36a to 36d is not limited to the above arrangement, and as a modification, the lead pins 36a to 36d may be arranged to be close to one side of the optical modulator integrated laser chip 22. According to this modification, the wire lengths of the feed paths 28a to 28d can be easily differentiated, and the positions of the lead pins 36a to 36d can be put together. Furthermore, as described in the first embodiment, it is possible to perform the deformation of the predetermined range Q using the regression line R and the deformation using ribbon feeders or the like instead of the feed paths 28a to 28d.

### REFERENCE SIGNS LIST

2,12,30,102 optical modulation device
4 substrate
5a to 5d semiconductor laser element
6a to 6d, 16a to 16d, 26a to 26d, 106a to 106d optical modulator
7a to 7d feed substrate
8a to 8d, 18a to 18d, 28a to 28d feed path
9 optical multiplexer
22 optical modulator integrated laser chip
31 cap
32 window
33 stem
34 block
35 sub mount
36a to 36i lead pin
41 Peltier element
42 thermistor
61 anode electrode
71 electrode pad
72 terminating resistor
73 ground electrode
74 line
75 wire
80 driver circuit

1. An optical modulation device comprising:
a first optical modulator having a first capacitance;
a second optical modulator having a second capacitance larger than the first capacitance;
a first feed path that has a first inductance and has one end connected to the first optical modulator; and
a second feed path that has a second inductance larger than the first inductance and has one end connected to the second optical modulator, wherein
a gap between a predetermined lower limit straight line and a predetermined upper limit straight line is set as a predetermined range in a graph in which an abscissa axis is set for inductances and an ordinate axis is set for capacitance values,
an inductance=670 nH and a capacitance value=0.05 pF in the graph define a first point,
an inductance=1340 nH and a capacitance=0.11 pF in the graph define a second point,
an inductance=2010 nH and a capacitance value=0.155 pF in the graph define a third point,
the lower limit straight line is a straight line passing through the first point and the third point in the graph,
the upper limit straight line is a straight line having a gradient equal to a gradient of the lower limit straight line and passing through the second point in the graph, the first inductance and the second inductance range from 670 nH to 2010 nH, and
the first capacitance, the first inductance, the second capacitance and the second inductance are determined so that a first coordinate determined by the first capacitance and the first inductance and a second coordinate determined by the second capacitance and the second inductance are contained within the predetermined range.

2. The optical modulation device according to claim 1, further comprising:
a first feed substrate for supplying an electric signal to another end of the first feed path; and
a second feed substrate for supplying an electric signal to another end of the second feed path, wherein
the first feed substrate includes a first terminating resistor and a first ground electrode, one end of the first terminating resistor is connected to the first optical modulator via the first feed path, another end of the first terminating resistor is connected to the first ground electrode,
the second feed substrate includes a second terminating resistor and a second ground electrode, one end of the second terminating resistor is connected to the second optical modulator via the second feed path, another end of the second terminating resistor is connected to the second ground electrode, and
the first terminating resistor and the second terminating resistor are equal to 120 Q or more.

3. The optical modulation device according to claim 1, further comprising:
a semiconductor substrate on which the first optical modulator and the second optical modulator are integrated;
a first feed substrate that is arranged on one side of the semiconductor substrate and connected to another end of the first feed path; and
a second feed substrate that is arranged on another side of the semiconductor substrate so as to sandwich the semiconductor substrate with the first feed substrate, and connected to another end of the second feed path.

4. The optical modulation device according to claim 1, further comprising:
a stem having a top surface and a block provided on the top surface;
a semiconductor chip that is mounted on a side surface of the block and has the first optical modulator and the second optical modulator integrated on a main surface of the semiconductor chip; and
a first lead pin and a second lead pin provided on the stem, wherein the first lead pin is connected to another end of the first feed path, and the second lead pin is connected to another end of the second feed path.
